(19) United States
(12) Patent Application Publication
(10) Pub. No.: US 2015/0300941 A1
(43) Pub. Date: Oct. 22, 2015

(54) METHOD FOR CHARACTERISING PARTICLES BY IMAGE ANALYSIS

(71) Applicant: COMMISSARIAT A L'ENERGIE ATOMIQUE ET AUX ENERGIES ALTERNATIVES, Paris (FR)

(72) Inventors: Emmanuelle Brackx, Goudargues (FR); Olivier Dugne, Orange (FR); Benoit Boichard, Elven (FR); Murielle Bertrand, Uzes (FR)

(73) Assignee: Commissariat à l'énergie atomique et aux énergies alternatives, PARIS (FR)

(21) Appl. No.: 14/443,571

(22) PCT Filed: Nov. 19, 2013
(86) PCT No.: PCT/EP2013/074189

§ 371 Date: May 18, 2015

(30) Foreign Application Priority Data
Nov. 20, 2012 (FR) 1261016

(51) Int. Cl. G01N 15/14; H01J 37/22; H01J 37/28

(52) U.S. Cl. CPC G01N 15/1429; H01J 37/28; H01J 37/222; H01J 2237/24571; H01J 2237/2801

(57) ABSTRACT

A method for characterizing particles including: producing at least one image of the particles of a sample with a scanning electron microscope, capturing and processing the image. The processing includes: for each usable particle, measuring maximum Feret length and minimum Feret width of same; defining a geometric model of the particle from the maximum Feret length and minimum Feret width of same; calculating a projected area of the particle from the geometric model and the minimum Feret width of same; calculating a volume of the particle from the geometric model, the projected area and the maximum Feret length of same; calculating a characteristic particle size on the basis of the geometric model, the minimum Feret width and maximum Feret length; calculating a volume shape factor from the volume and characteristic size.

### TECHNICAL FIELD

The present invention relates to a method for dimensionally and morphologically characterising particles of a divided solid or powder. Knowledge of the size and shape of the particles of the powder is without any doubt an important parameter in the characterisation of a powder. The size and the shape of the particles condition the behaviour of the powder, such as the flow, segregation, fluidity, crumbling, volatility, solubility thereof. The size of the particles of the powder very often enters into industrial and commercial criteria that are highlighted, such as filterability, clogging, assimilation for a medicine, atmospheric pollution, pelletisation, etc.

The characterisation of the structure of powders is very important for understanding and controlling their physical or chemical interactions with any other solid or fluid phase with which they enter into interaction.

For a spherical particle, a single quantity, its diameter, characterises its size. This quantity makes it possible to access, in addition to its surface area, its volume. But, in practice, a powder is formed of solid particles having a more complex shape and different sizes. For more complex shapes, the number of quantities that need to be known to determine the size increases.

### STATE OF THE PRIOR ART

The most widespread measurements of the size of divided solid particles, in the case of powders, the particles of which are of average size (between around 1 and 2000 micrometres) take place generally by laser diffraction, impedance variation or image analysis.

The particle size measurement carried out by laser diffractometers is based on light diffusion (diffraction, reflection and refraction) of a monochromatic radiation from a laser through a suspension of particles.

The particle size measurement carried out by image analysis is performed on static particles.

The acquisition of the shape of the particles is much more difficult. Image analysis methods are generally based on the use of an optical microscope.

The thesis “Characterisation of pigment particles by scanning electron microscope and image analysis programs” of Mikko Linnala defended in 2008 is also known.

In this document, a method is proposed for analysing pigment type particles, for example talc, clay, calcium carbonate, titanium dioxide, by taking images with a scanning electron microscope and analysing the images with image processing software. The scanning electron microscope makes it possible to obtain better precision than the optical microscope.

The software programmes employed are the Inca Feature software of the firm Oxford Instrument or the Poikkiprogram software of UPMKymmene Oyj/VTT Technical Research Centre of Finland.

The analysis of images makes it possible to determine the aspect ratio of the diameter or elongation factor and a shape factor SF of the particles (for an evaluation in three dimensions):

SF=d_{S}/(d_{I}·d_{L})^{1/2}

with d_{S} the smallest dimension of the particle, d_{I} the intermediate dimension of the particle, d_{L} the largest dimension of the particle. The aspect ratio is defined as the ratio of the minimum Feret width over the maximum Feret length. The maximum Feret length and the minimum Feret width are the distances between two tangents parallel to opposite sides of the particle. The maximum Feret length Lmax and the minimum Feret width Imin of a particle 1 are represented in FIG. 1.

The aspect ratio makes it possible to characterise the shape anisotropy of the particle, that is to say its elongation. It is defined as the ratio of the maximum Feret length Lmax and minimum Feret width Imin. It only reflects the elongation of the particle and its symmetry but does not enable a distinction between a spherical or cubic particle to be made.

The shape factor SF does not make it possible either to make a distinction between a substantially spherical particle and a substantially cubic particle.

These two parameters do not make it possible to characterise in a reliable manner the shape of particles. This method is thus not suitable for a large number of morphologies. Yet particles can have very diverse morphologies in addition to spherical morphology: angular, acicular, dendritic, etc.

### DESCRIPTION OF THE INVENTION

The present invention specifically relates to a method for characterising particles of a divided solid by image analysis which automatically makes it possible to know in a more precise and more reliable manner than in the prior art the real shape of the particles and their dimension.

Another aim of the invention is to propose a method for characterising particles which is suitable for all types of particles whereas certain laser diffraction techniques are not suitable, particularly for particles which cannot be made to move by magnetic stirring.

Yet another aim of the invention is to propose a method for characterising particles which makes it possible to easily access from the image the average of the equivalent diameters of the particles as well as the particle size dispersion around the average value.

To achieve this, the present invention relates to a method for characterising particles of a divided solid comprising the following steps:

Producing at least one image of the particles of a sample of the divided solid with a scanning electron microscope;

Capturing the image delivered by the scanning electron microscope and processing the image, in which the processing operation consists of:

for each so-called usable particle, measuring the maximum Feret length and the minimum Feret width of same;
defining a type of geometric figure to which the particle corresponds from the maximum Feret length and the minimum Feret width of same, this type of geometric figure being called geometric model;
calculating a projected area, in the plane of the image, of the particle from the geometric model and minimum Feret width of same;
calculating a volume of the particle from the geometric model, the projected area and maximum Feret length of same;
calculating a characteristic particle size, the characteristic size being the square root of the sum of its squared length, squared width and squared height, its length, its width and its height being obtained from the geometric model, the minimum Feret width and the maximum Feret length;
calculating a volume shape factor of the particle as being the ratio of the volume over the characteristic size cubed.

Before the step of producing the image, the sample is placed on a conductive pad before placing it in the scanning electron microscope, wherein the sample is a dry sample or a wet sample.

The determination of the geometric model may take into account the shape of the particle given by the image.

The image captured is a greyscale image and the processing includes, before the measurement, a step of detecting particles in the image by thresholding their grey scale intensity.

It is preferable that the processing of the image provides to reject among the particles detected conjoined particles so as to only conserve separated particles, which are the usable particles.

The scanning electron microscope is coupled to image analysis software to carry out the processing.

The processing may further consist of:
calculating an equivalent diameter of the usable particles of the sample;
defining several granulometric classes of the particles on the basis of the equivalent diameter of the particles;
calculating a centre of each granulometric class or characteristic equivalent diameter by class centre;
counting the number of particles in each granulometric class;
calculating a percentage by number of particles in each granulometric class;
converting the percentage by number of particles in each granulometric class into a percentage by volume of particles in each granulometric class;
carrying out a modelling of the size distribution by volume of the characteristic equivalent diameters;
calculating an average of the characteristic equivalent diameter of the particles;
calculating a standard deviation of the characteristic equivalent diameter of the particles.

Advantageously, the equivalent diameter is an equivalent circle diameter.

The modelling of the size distribution by volume of the characteristic equivalent diameters comprises a step of calculating a cumulative increasing function from the percentage by volume of particles in each granulometric class, a step of calculating an expected value by application of a distribution law, a step of modelling the distribution law with minimisation of the residuals of all the values of the expected value by the least squares method.

The distribution law may be a normal or log-normal distribution law.

The modelling is carried out using statistical processing software.

### BRIEF DESCRIPTION OF THE DRAWINGS

The present invention will be better understood on reading the description of examples of embodiment given for purely indicative purposes and in no way limiting and by referring to the appended drawings in which:

FIG. 1 illustrates the maximum Feret length and the minimum Feret width for a particle as well as its equivalent diameter;

FIGS. 2A to 21 are images of each of the samples under scanning electron microscope;

FIG. 3 is a schematic view in three dimensions of a prismatic particle with hexagonal base like those of sample G;

FIG. 4 illustrates the distribution of the volume shape factor of sample G;

FIGS. 5A1, 5B1, 5C1, 5D1, 5E1, 5F1, 5G1, 5H1, 5I1 illustrate the percentage by volume of particles on the basis of the characteristic equivalent diameter obtained for samples A to I respectively by the method of the invention and potentially one or two laser diffraction techniques;

FIGS. 5A2, 5B2, 5C2, 5D2, 5E2, 5F2, 5G2, 5H2, 5I2 illustrate the normed cumulative function of the percentage of each measured characteristic equivalent diameter obtained for samples A to I respectively by the method of the invention and potentially one or two laser diffraction techniques.

### DETAILED DESCRIPTION OF PARTICULAR EMBODIMENTS

The method for characterising particles which is the subject matter of the invention by image analysis by scanning electron microscope will now be described. In the examples that will be described, the method has been applied to powders of different natures:

Several samples of powders were available:

1° glass beads of the American NIST (National Institute of Standards and Technology). Three samples of calibrated and certified beads have been studied, the diameters indicated are those of the manufacturer, they were measured by optical microscopy.

Sample A:

Diameter: 42.3±1.1 micrometres

Sample B:

Diameter: 139±2.6 micrometres

Sample C:

Diameter: 198±3.4 micrometres)

2° powder of metal copper from the firm Sigma Aldrich, of chemical purity greater than 99.8% of which the granulometric characteristics announced by the manufacturer are for sample D between 200 and 600 micrometres and for sample I of 50 micrometres, in the form of dendrites. The shape of the particles of these samples is more complex than that of the beads.)

3° powder of garnet ore of the nesosilicates group supplied by Beckman Instruments. For sample E the average equivalent volume diameter given by the manufacturer is 15.07±1.8 micrometres and for sample F the average equivalent volume diameter given by the manufacturer is 32.9±0.99 micrometres.)

4° powder of mixed uranium-neodymium oxalate (sample G) and powder of neodymium oxalate (sample H) from an oxalic precipitation method. The particles of these powders are synthetic particles, the morphology of which depends on the molecular and structural arrangement of their constituent atoms and is independent of the mechanical manufacturing method. These samples have the shape of rods. The particles of sample G are of prismatic type with hexagonal base. The particles of sample H are of parallelepiped type.

Samples D, E, F are samples of powder of known dimensions and announced by the manufacturer.

Samples of these powders are deposited on a pad made of conductive material before being placed under a scanning electron microscope.

The preparation of the samples has been done according to two techniques and the choice of one or the other of the techniques depends on the samples.

The first technique is a dry technique, a thin mono-particulate deposition is carried out on a glass slide then transferred onto an electrically conductive pad, for example made of carbon. The second technique is a wet technique, using a dilution in solution of the powder, a de-agglomeration of the particles by ultrasounds and a deposition on the electrically conductive pad for example made of aluminium.

Samples A, B, C, D, E, F and I have been prepared according to the first technique and samples G and H have been prepared according to the second technique.

An image or several images are taken by the scanning electron microscope, an image may correspond to one or more measurement fields. These images are high resolution images. The magnification of the microscope depends on the size of the particles. The scanning electron microscope enables a variation of magnification from 1 to 1000000, this variation being greater than that of an optical microscope. The use of a high resolution microscope is recommended for taking images of particles of nanometric and micrometric sizes. This scanning electron microscope is for example a Supra 55 high resolution field effect scanning electron microscope from Carl Zeiss. Each image is captured by a detector and processed by image processing software coupled to the scanning electron microscope. It may be INCA Feature software developed by the firm Oxford Instrument for forensic scientists but this is not limiting. This software enables the automation of a large number of analysis fields of the sample on the pad and offers a suitable statistic of measurements. It is assumed in the example described that the pad comprises two contiguous analysis fields.

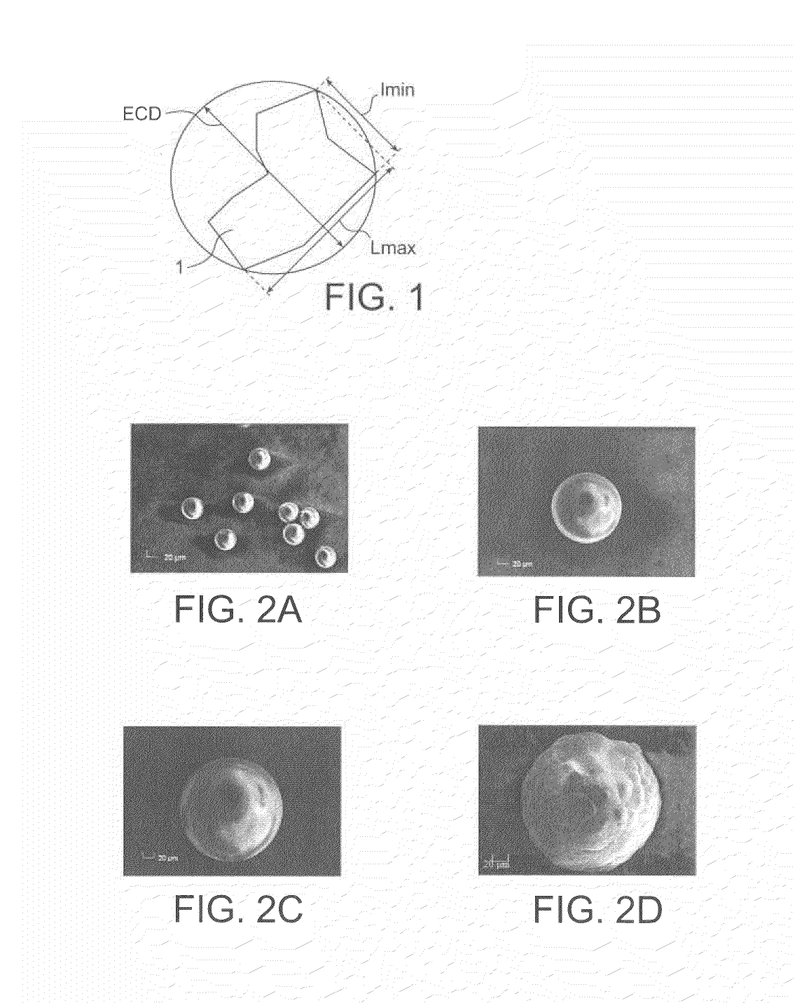

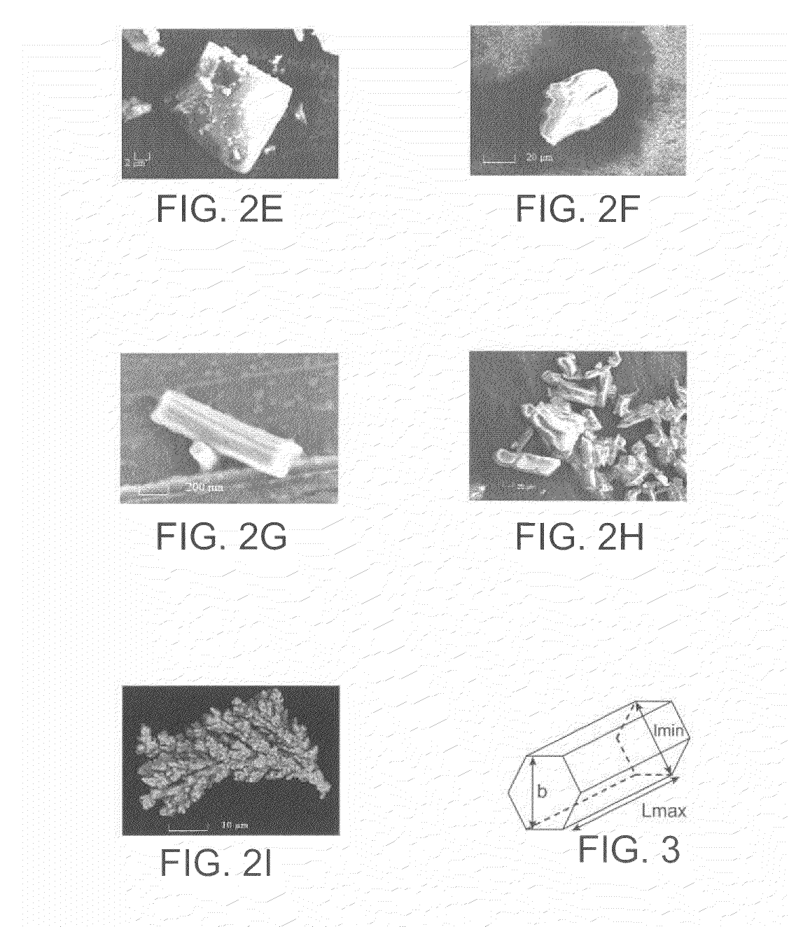

FIGS. 2A to 2I show an image taken by the electron microscope of different samples ranging from A to I with a very large magnification such that several particles only appear.

This software comprises a specific module for the detection of shapes by analysis of the image taken by the scanning electron microscope. The image captured is a greyscale image. The particles of the sample observed are detected by an intensity threshold processing of greyscales of the image. Several threshold scales may be employed to improve detection efficiency.

It is possible, moreover, to carry out one or more specific processing (s) of the image aiming at the separation of the particles from each other for example by erosion, separation, expansion, greyscales, etc. Certain usable particles are thus conserved and measured and others are not taken into account.

Thus in sample A, the number of particles counted is 4643, the measurements have been made on 420 observation zones with images taken with a magnification of 225.

In sample B, the number of particles counted is 1467, the measurements have been made on 30 observation zones with images taken with a magnification of 25.

In sample C, the number of particles counted is 1169, the measurements have been made on 487 observation zones with images taken with a magnification of 25.

In sample D, the number of particles counted is 195, the images have been taken with a magnification of 25.

In sample E, the number of particles counted is 4052, the measurements have been made with a magnification of 300.

In sample F, the number of particles counted is 1818, the measurements have been made with a magnification of 300.

In sample G, the number of particles counted is 901, the measurements have been made on 4 400 observation zones with images taken with a magnification of 40 000.

In sample H, the number of particles counted is 936, the measurements have been made on 150 observation zones with images taken with a magnification of 5 000.

In sample I, the number of particles counted is 2216, the measurements have been made on 88 observation zones with images taken with a magnification of 25.

An image corresponds to an observation zone.

The maximum Feret length Lmax and the minimum Feret width Imin of each usable particle is then measured. For a particle of sample G, Imin=1.218683839 micrometres and Lmax=2.215934753 micrometres have been noted for example.

Thanks to the measurements of the maximum Feret length and the minimum Feret width for each particle, a geometric model of the particle of the sample is determined. Geometric model is taken to mean the type of geometric figure which corresponds to the particle: it may be a solid, for example, of sphere type, parallelepiped, prism with hexagonal base, etc.

It is also possible to take into account morphology information supplied by the high resolution images for the determination of the geometric model. This geometry information corresponds to the shape of the particle given by the image. In the image, it may be seen whether the particle is elongated like a needle, round as in FIG. 2, polygonal, etc.

In the example considered, the geometric model may apply to particles of constant geometry such as the particles of samples A, B, C, D which are spherical, the particles of sample G which are hexagonal prisms, the particles of sample H which are parallelepipeds.

A projected area in the plane of the image for the particle considered is then calculated from the geometric model determined and from the minimum Feret width Imin. This projected area is conventional in the field of particle characterisation. For example for sample G while referring to FIG. 3, the area S is that of the base which is hexagonal given by the following formula:

$$S = 3 \frac{\sqrt{3}}{2} \times {( \frac{( 1 min )}{2} )}^{2}$$

For the considered particle of sample G, its projected area S is 0.964659396 square micrometres.

The calculation of the projected area S does not pose any problem for the other samples since the geometric model has been determined.

A volume V of the considered particle is then calculated from the maximum Feret length Lmax, from the projected area S calculated previously and from the geometric model. This volume calculation does not pose any problem for those skilled in the art.

Thus for sample G, the volume meets the following formula:

V=S×Lmax

For the considered particle of sample G its volume is 2.13762282 cubic micrometres.

All types of particles may be modelled by a characteristic size L which is defined as the square root of the sum of its squared length, its squared width and its squared height. Its length, its width are obtained, by image analysis, from its maximum Feret length, its minimum Feret width and the geometric model determined beforehand leads to its height. In the case of a parallelepiped particle, the characteristic size is its diagonal.

The characteristic size L of the considered particle is thus calculated from the Feret dimensions and from the geometric model of the particles of the sample considered. For prismatic particles with hexagonal base, this characteristic size L is equal to:

$$L = \sqrt{{( \frac{( 1 min )}{2} )}^{2} + L {max}^{2} + {b}^{2}}$$

The quantity b is given by:

$$b = 2 sin ( {60}^{∘} ) ( \frac{( 1 min )}{2} )$$

FIG. 3 shows such a particle in the form of a regular hexagonal straight prism.

For the considered particle of sample G its characteristic size L is equal to 6.39555713 micrometres.

The following step is the calculation of the volume shape factor φV of the particles of the sample considered. This volume shape factor is given by:

φV=V/L³

For the considered particle of sample G, its volume shape factor 4V is equal to 0.00817139.

The volume shape factor makes it possible to better characterise morphologically the particles of the sample than the shape factor SF determined in the aforementioned thesis.

The calculation of the volume shape factor of the particles of sample G has great interest, in particular, in the case of kinetic studies (of nucleation, growth or agglomeration) and the development of the modelling of methods of co-precipitation of uranium and neodymium oxalic. The determination of the volume shape factor by the method of the invention makes it possible to bring greater precision to the characterisation of a very large number of particles measured in the sample. The exploitation of this volume shape factor automatically provides a robust, statistically significant solution, complete for the modelling of the formation of precipitates.

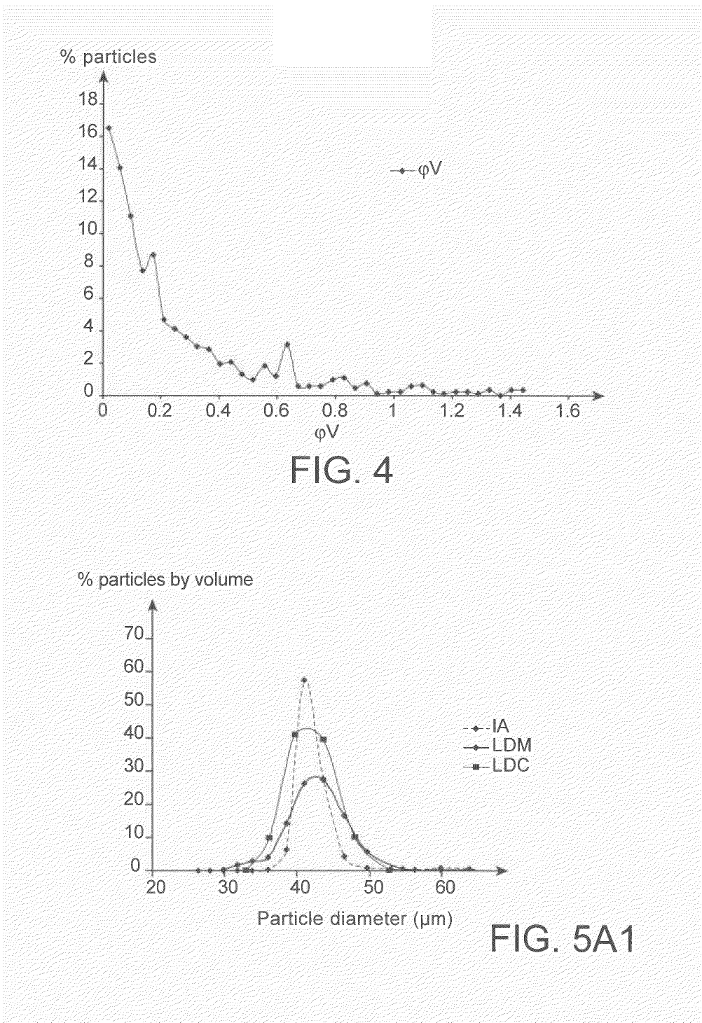

From the volume shape factors obtained for the particles of sample G, it is possible to draw up the percentage distribution of the volume shape factor of the particles of sample G as illustrated in FIG. 4. It may be seen that the majority of the particles have a volume shape factor equal to 0.019 and this is in agreement with the case of extended prismatic volumes (10*1*1) and with the observation by an observer of the image taken by the electron microscope.

It is advantageous to also use image analysis to carry out a granulometric and morphological analysis of the studied sample, so as to acquire key information on the population of the sample.

Notably for samples G and H, the particles of which are crystals, granulometric analysis makes it possible to provide quantitative growth information in kinetic nucleation studies.

In such an analysis, the measured particles of the sample are distributed in granulometric classes as a function of an equivalent diameter which it is necessary to calculate. In the example described, the equivalent diameter employed is the equivalent circle diameter ECD, which is the diameter of a circle having the same area S as that of the particle. Said equivalent diameter is expressed by:

ECD=\sqrt{4S/π}

This equivalent circle diameter is illustrated in FIG. 1.

Another equivalent diameter could obviously have been used, such as the equivalent volume diameter which is the equivalent diameter of a sphere having the same volume as that of the particle, or instead the equivalent surface diameter which is the diameter of a sphere having the same surface as the particle or even the equivalent surface-volume diameter which is the diameter of a sphere having the same surface/volume ratio as the particle.

The equivalent circle diameter ECD of all the measured particles of the image is calculated and these equivalent diameters are distributed into several granulometric classes.

Each granulometric class is limited by two equivalent diameters ECD1 and ECD2. One then calculates, for each granulometric class, its centre Ce. The centre Ce of the granulometric class represents the diameter of an average sphere illustrating the granulometric class, it is the characteristic equivalent diameter per fraction size centre. Said centre Ce is given by the formula:

Ce=(ECD1+ECD2)/2

The total number N of measured particles in the image and the number M of particles in each granulometric class is counted.

A percentage PN by number M of particles in each granulometric class can then be calculated. This percentage is expressed by:

PN=(M/N)100

This percentage by number PN is going to be converted into a percentage by volume PV. To do this, the volume VC of the particles per granulometric class centre is calculated:

VC=4/3·π(Ce/2)³M

The percentage by volume PV of the particles in each granulometric class is then obtained. This percentage is expressed by:

PV=(Vc/N)100

A modelling is then carried out of the size distribution by volume of the characteristic equivalent diameters following a normal law or log-normal law granulometric model. They are characteristic equivalent diameters corresponding to each class centre.

Statistical processing software is used, such as Lumière version 5.45 software for example.

The starting point is the percentage by volume PV of the particles in each granulometric class. A cumulative increasing function is calculated from the percentage by volume PV in each granulometric class. To do so a percentage by volume PV is added with its neighbour and divided by 100.

An expected value μ is calculated by application of a distribution law of the inverse normal law to the values of the cumulative increasing function calculated previously. In a variant, it may be the log-normal law instead of the normal law.

The normal law is modelled by minimisation of the residuals of all of the values of the expected value by the least squares method. The same thing is done with the log-normal law.

The average of the characteristic equivalent diameter of the particles and the standard deviation of the characteristic equivalent diameter are calculated.

The size distribution by volume of the characteristic equivalent diameters of the particles is expressed in the following manner:

DMI=a(0)+a(1)×μ

With a(0) the average value of the characteristic equivalent diameter of standard deviation σa(0) and a(1) the distribution width with a standard deviation σa(1), μ being the expected value.

The results obtained with the samples A to I presented above will now be discussed.

In order to be able to validate the results of the granulometric analysis by image analysis IA by the method of the invention, for certain of these samples two additional granulometric analyses were carried out, one by a Beckman Coulter LS 13320 laser granulometer (LDC) and the other by a Malvern Mastersizer X laser granulometer (LDM). It is thereby possible to compare the results of all the analyses with each other.

These devices are based on light scattering. The powders are suspended in a diluent, for example a mixture of deionised water and ethanol by magnetic stirring.

The first granulometer is particularly adapted to particle sizes from 0.04 micrometres to 2000 micrometres and the second is particularly adapted to particles from 0.1 micrometres to 2000 micrometres.

The data obtained have been modelled in the same way as has been described for the method of the invention.

The results concerning the averages of the characteristic equivalent diameters and the standard deviations for the particles of samples A to C, obtained by the two LDC and LDM laser diffraction techniques and by the IA image analysis method which is the subject matter of the invention, are grouped together in table n°1. The values announced by the NIST are also shown in this table.

TABLE NO 1

| | NIST | | LDM | | LDC | | IA | |
|---|---|---|---|---|---|---|---|---|
| | | Standard | | Standard | | Standard | | Standard |
| | Average | deviation | Average | deviation | Average | deviation | Average | deviation |
| Sample | μm | μm | μm | μm | μm | μm | μm | μm |
| A | 42.30 | 1.50 | 42.33 | 0.31 | 39.91 | 0.11 | 44.33 | 1.90 |
| B | 139.00 | 2.90 | 139.65 | 1.50 | 131.15 | 5.40 | 139.24 | 9.99 |
| C | 198.00 | 6.40 | 191.47 | 2.06 | 192.37 | 21.91 | 195.37 | 3.54 |

The results are not significantly different, the three methods are in coherence with the values announced by the NIST.

Moreover, table n°2 below gives the results of a hypothesis test, such as the t test or Student test carried out on the comparison of the averages of the characteristic equivalent diameters obtained by the LDM, LDC, IA techniques with those of the NIST.

A hypothesis test is an approach consisting in evaluating a statistical hypothesis as a function of a set of data (sample). This test enables the comparison of the values of the average from two techniques. The values are significantly different if t is greater than 2.

TABLE NO 2

| | Sample | | |
|---|---|---|---|
| Data compared | A | B | C |
| NIST-LDM | 0.02 | 0.20 | 0.97 |
| NIST-LDC | 1.59 | 1.28 | 0.25 |
| NIST-IA | 0.84 | 0.02 | 0.36 |

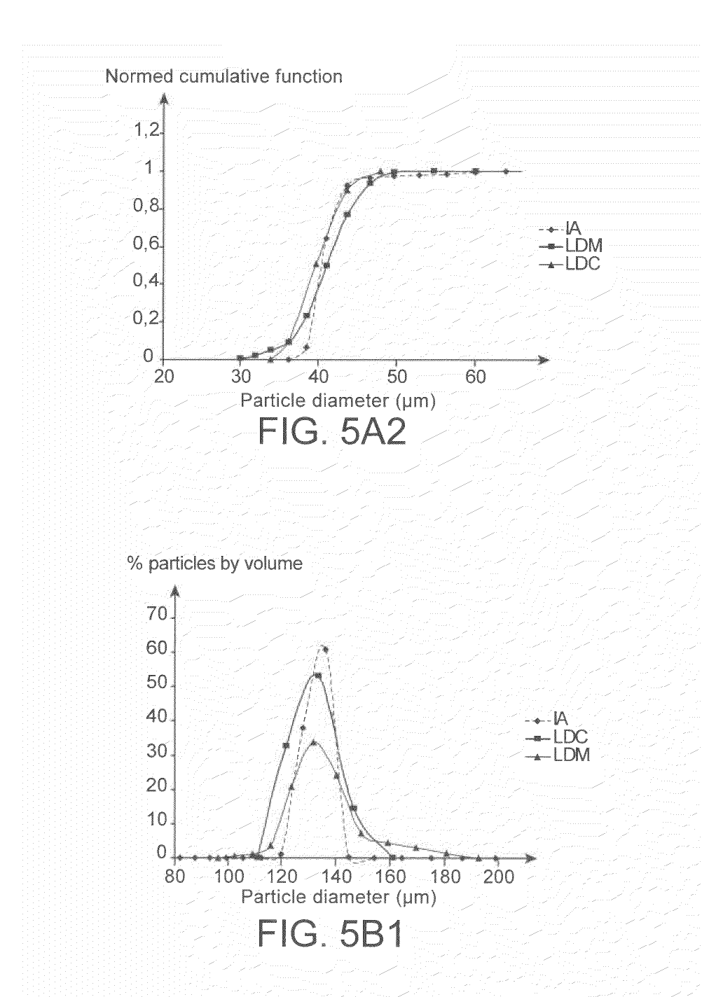

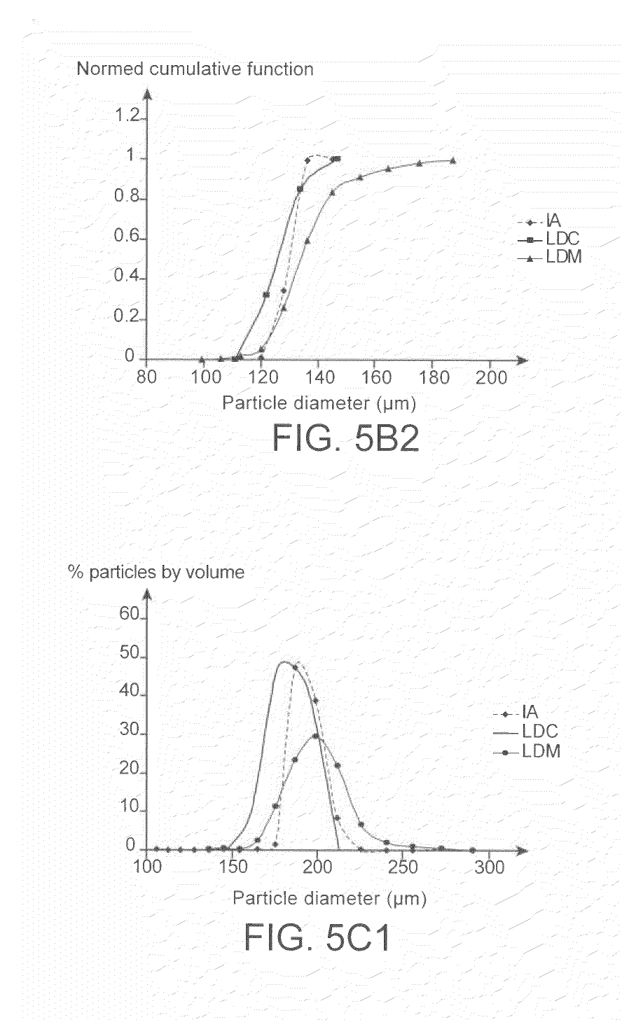

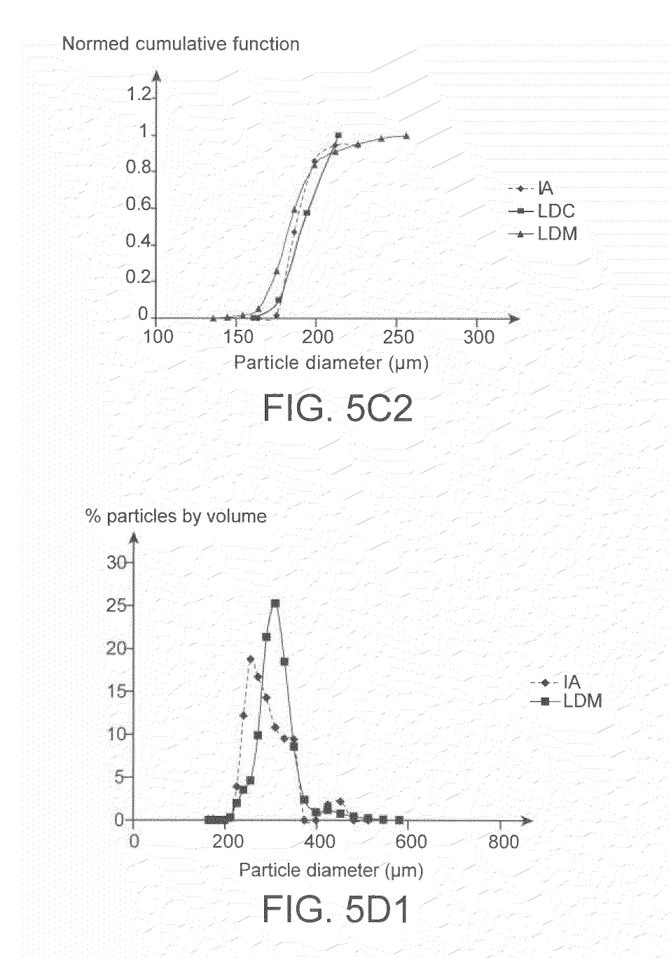

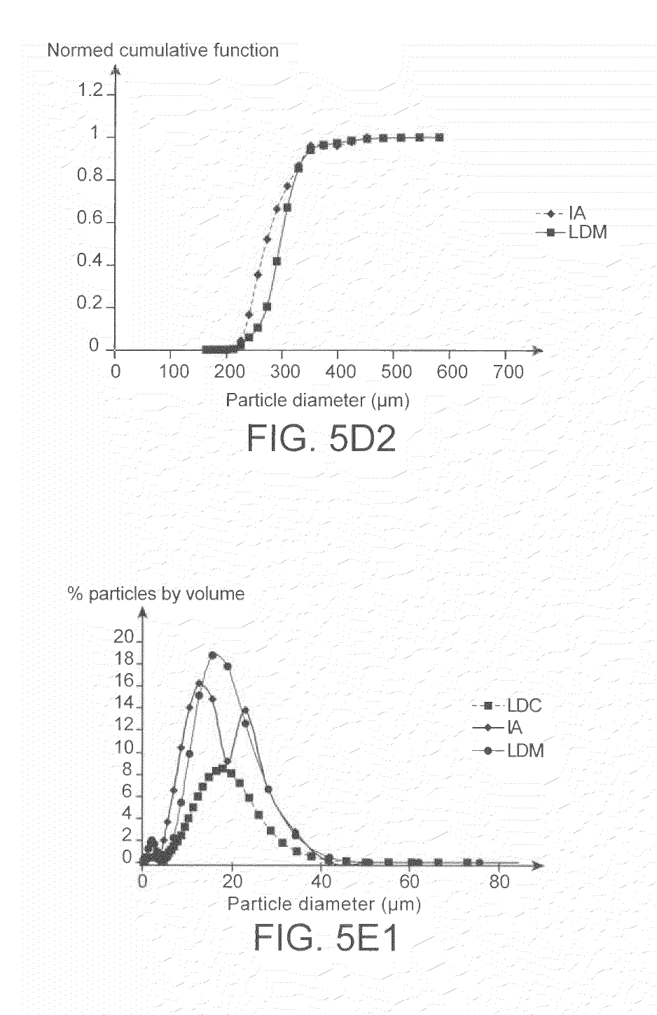

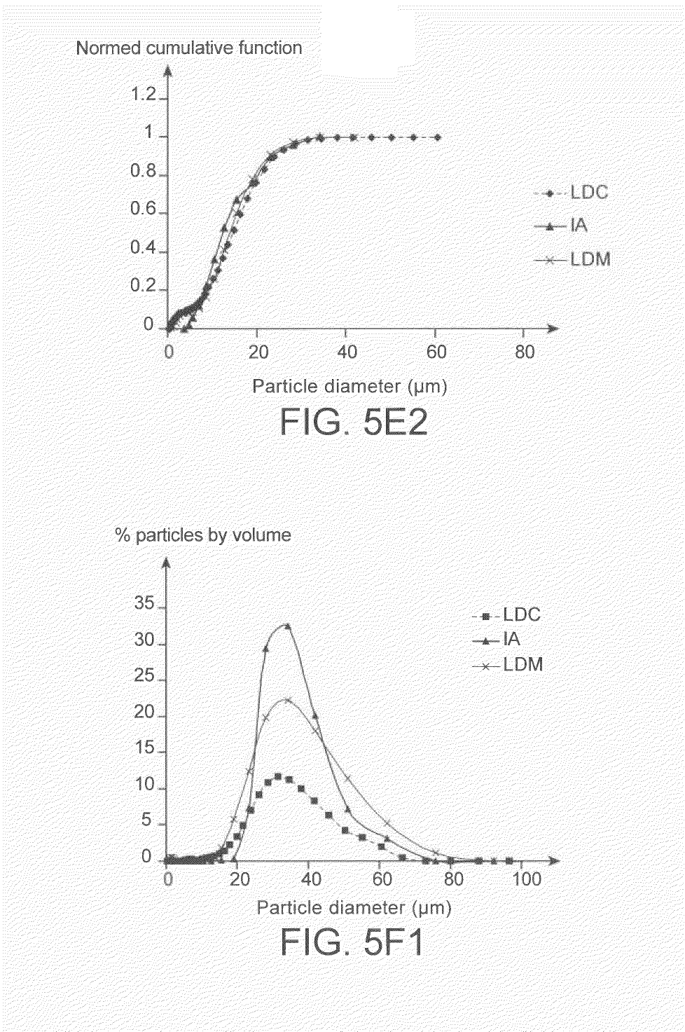

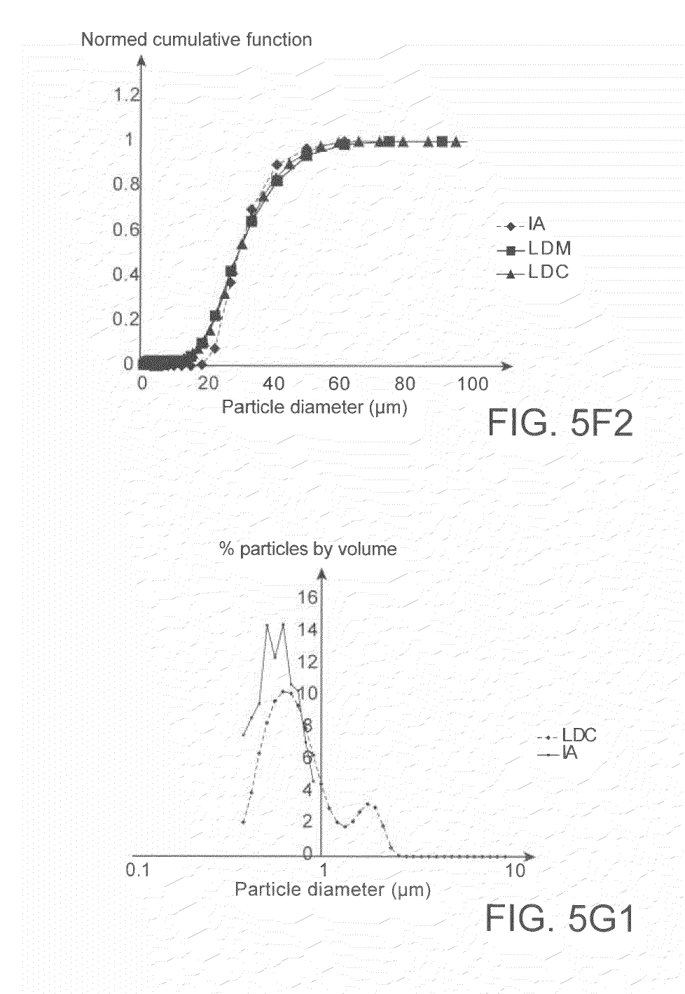

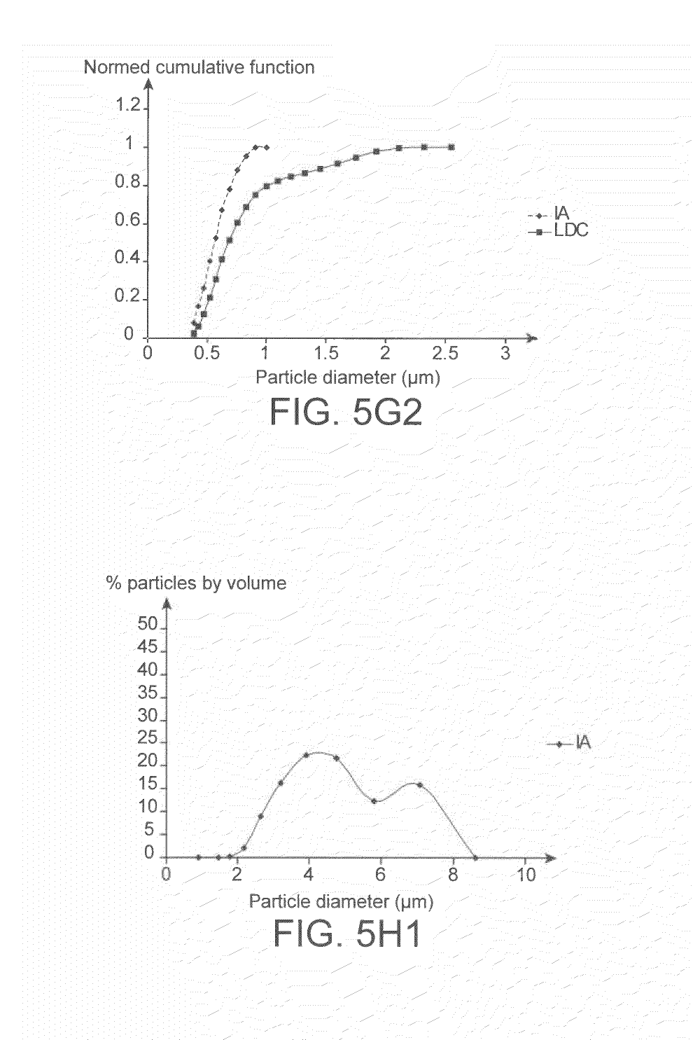

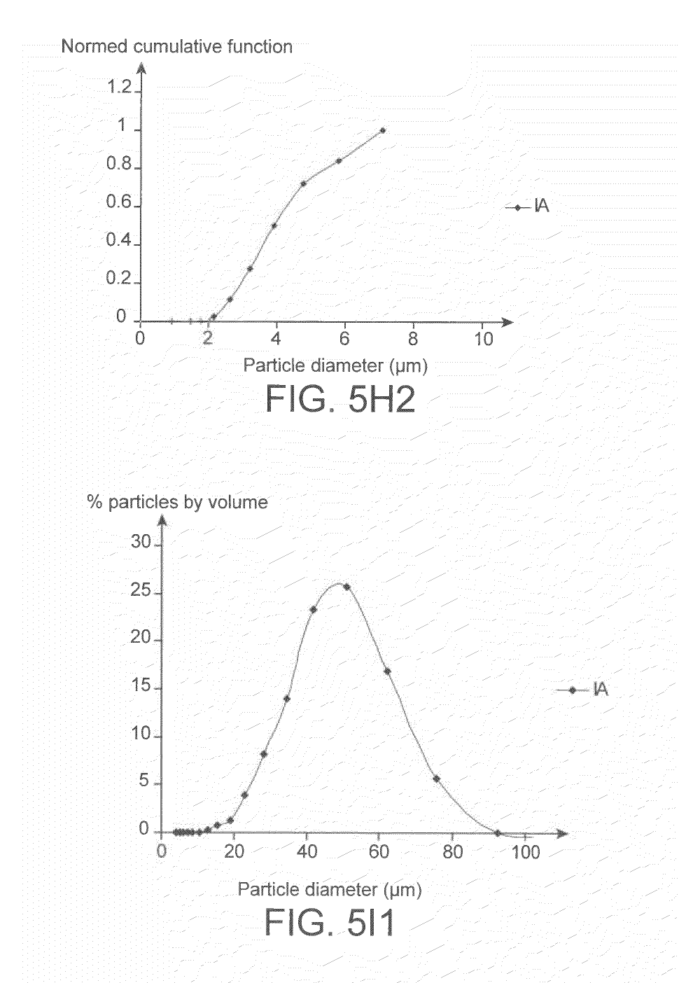

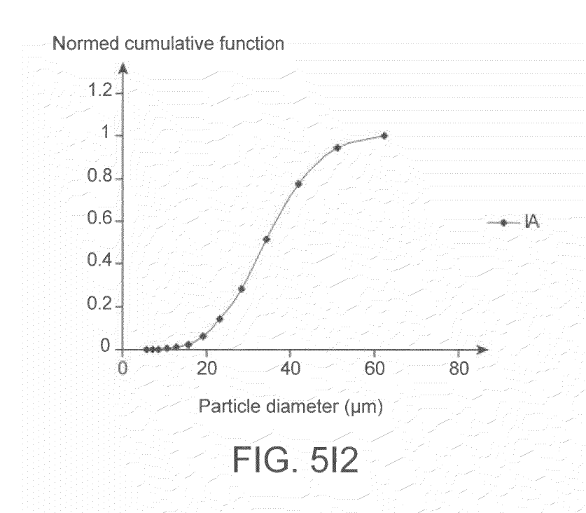

FIGS. 5A1, 5A2, 5B1, 5B2, 5C1, 5C2 illustrate the granulometry data of the particles of samples A, B, C obtained by the image analysis method which is the subject matter of the invention and by the two LDC and LDM laser diffraction techniques. More particularly, FIGS. 5A1, 5B1, 5C1 illustrate the percentage by volume of particles on the basis of the characteristic equivalent diameter and FIGS. 5A2, 5B2, 5C2 illustrate the normed cumulative function on the basis of the characteristic equivalent diameter. The normed cumulative function thus enables the calculation of a probability density of the characteristic diameters and the calculation of the characteristic average diameter.

The data obtained from the measurements are entirely coherent and satisfactory with the data announced by the manufacturer.

Table n°3 below groups together the results concerning the averages of the characteristic equivalent diameters and the standard deviations for the particles of sample D, obtained by the LDM laser diffraction technique and by the image analysis method IA which is the subject matter of the invention.

TABLE NO 3

| | |
|---|---|
| LDM | IA |

| | | Standard | | Standard |
|---|---|---|---|---|
| | Average | deviation | Average | deviation |
| Sample | μm | μm | μm | μm |
| D | 309.59 | 11.35 | 295.2 | 5.65 |

The result of the Student test is t=1.13. The distributions are not significantly different between the two LDM and IA techniques according to the invention.

In the same way as has been described previously, FIGS. 5D1 and 5D2 illustrate the granulometry data of the particles of sample D obtained by the IA image analysis method which is the subject matter of the invention and by the LDM laser diffraction technique.

Table n°4 groups together the results concerning the averages of the characteristic equivalent diameters and the standard deviations of sample E. The two LDM and LDC laser granulometry techniques have been used.

TABLE NO 4

| | Manufacturer's | | | | | | | |
|---|---|---|---|---|---|---|---|---|
| | value | | LDM | | LDC | | IA | |
| | | Standard | | Standard | | Standard | | Standard |
| | Average | deviation | Average | deviation | Average | deviation | Average | deviation |
| Sample | μm | μm | μm | μm | μm | μm | μm | μm |
| E | 15.07 | 1.8 | 14.65 | 0.41 | 16.81 | 0.52 | 14.92 | 0.89 |
| F | 32.09 | 0.99 | 31.99 | 0.41 | 31.22 | 1.12 | 32.69 | 0.97 |

The Student test carried out between each of the averages obtained by the measurements and the value of the diameter given by the manufacturer (15.07 micrometres) for sample E makes it possible to see that the averages obtained by the LDM, LDC and IA techniques according to the invention are not significantly different to that given by the manufacturer:

manufacturer—LDM: t=0.23
manufacturer—LDC: t=0.93
manufacturer—IA: t=0.07

The three techniques are comparable. On the other hand, if the results of the three LDC, LDM and IA techniques according to the invention are compared with each other one obtains:

LDC-IA: t=1.84
LDM-IA: t=0.27
LDC-LDM: t=3.25

The two averages obtained by the LDC and LDM techniques are significantly different since t is greater than 2.

In the same way as has been described previously, FIGS. 5E1 and 5E2 illustrate the granulometry data of the particles of sample E obtained by the IA image analysis method which is the subject matter of the invention and by the two LDC and LDM laser diffraction techniques.

FIGS. 5F1 and 5F2 illustrate the granulometry data of the particles of sample F obtained by the IA image analysis method which is the subject matter of the invention and by the two LDC and LDM laser diffraction techniques.

Table n°4 also groups together the results concerning the averages of the characteristic equivalent diameters and the standard deviations of sample F.

For this sample F, the Student test carried out between each of the values obtained for the comparison of the averages makes it possible to conclude that the averages obtained from measurements made by the LDC and LDM techniques are not significantly different to those obtained from measurements made by the IA technique which is the subject matter of the invention.

LDC-IA: t=0.41
LDM-IA: t=0.66

The Student test carried out between each of the averages obtained from three measurements and the average given by the manufacturer gives respectively the following values:

LDM-manufacturer: t=0.09
LDC-manufacturer: t=0.58
LDC-manufacturer: t=0.43

The three LDC, LDM and IA techniques according to the invention give comparable and reliable results.

The final samples G, H and I are samples of powders of which the particles have complex shapes.

The measurements on sample G have been made by the IA technique according to the invention, by the LDC laser diffraction technique but not by the LDM laser diffraction technique.

FIGS. 5G1 and 5G2 illustrate the granulometry data of the particles of sample G obtained by the IA image analysis method which is the subject matter of the invention and by the LDC laser diffraction technique. The distribution obtained by the LDC technique is bimodal, which could be due to the presence of agglomerates. There was no sorting step.

Table n°5 also groups together the results concerning the averages of the characteristic equivalent diameters and the standard deviations of sample G.

TABLE NO 5

| | |
|---|---|
| LDC | IA |

| | | Standard | | Standard |
|---|---|---|---|---|
| | Average | deviation | Average | deviation |
| Sample | μm | μm | μm | μm |
| G | 0.69 | 0.03 | 0.56 | 0.04 |
| H | | | 4.21 | 0.18 |

The characteristic equivalent diameters obtained by the two techniques are of the same order of magnitude but are statistically different (t=2.56) due to the low values of the standard deviation.

The use of the method according to the invention by IA image analysis makes it possible to properly characterise particles of micrometric or even nanometric size as a complement to laser granulometric analysis.

Table n°5 also groups together the results concerning the averages of the characteristic equivalent diameters and the standard deviations of sample H.

FIGS. 5H1 and 5H2 illustrate the granulometry data of the particles of sample H obtained uniquely by the IA image analysis method which is the subject matter of the invention.

FIGS. 5I1 and 5I2 illustrate the granulometry data of the particles of sample I obtained uniquely by the IA image analysis method which is the subject matter of the invention.

There is impossibility of carrying out measurements by LDC due to the magnetic stirring cell which does not function with copper due to the magnetic capture of the copper particles. There is impossibility of carrying out measurements by LDM due to the considerable roughness of the particles creating an agglomeration of the particles and a blocking of the device. The considerable roughness of the particles is linked to their method of manufacture at high temperature.

Table n°6 groups together the results concerning the averages of the characteristic equivalent diameters and the standard deviations of sample I.

TABLE NO 6

IA

| | | Standard |
|---|---|---|
| | Average | deviation |
| Sample | μm | μm |
| I | 42.58 | 0.47 |

The interest of granulometry and morphology measurements by the image analysis method which is the subject matter of the invention is great because it is suitable for many morphologies of particles, spherical, elongated, rough, and for many materials even those which are not suitable for LDC or LDM laser diffraction due to their roughness or their chemical nature.

Another interest of the present invention is to enable a granulometry measurement of solid particles of sizes extending over a wide range, for example between 0.1 micrometres and 1 000 micrometres.

The measurement of the volume shape factor and the granulometry analysis can take place simultaneously from a same image. The granulometry analysis with the average of the diameters and the standard deviation is suitable for particles of small dimensions of the order of a tenth of a micrometre.

The determination of the volume shape factor is a measurement that is inaccessible by the laser diffraction technique.

The method for characterising particles according to the invention is suitable not just for particles of simple shape but also for particles of complex shape, for agglomerates and for the crystallites that constitute said agglomerates.

Although several examples of embodiment of the present invention have been represented and described in a detailed manner, it will be understood that different changes and modifications may be made without going beyond the scope of the invention.

1-11. (canceled)

12: A method for characterizing particles of a divided solid comprising:
producing at least one image of the particles of a sample of the divided solid with a scanning electron microscope;
capturing the image delivered by the scanning electron microscope and processing the image, the processing comprising:
for each usable particle, measuring maximum Feret length and minimum Feret width of same;
defining a type of geometric figure to which the particle corresponds from the maximum Feret length and minimum Feret width of same, wherein a type of geometric figure is a geometric model;
calculating a projected area, in the plane of the image, of the particle from the geometric model and minimum Feret width of same;
calculating a volume of the particle from the geometric model, the projected area, and maximum Feret length of same;
calculating a characteristic particle size, the characteristic size being the square root of the sum of its squared length, its squared width and its squared height, its length, its width and its height being obtained from the geometric model, the minimum Feret width and the maximum Feret length;
calculating a volume shape factor of the particle as being the ratio of the volume over the characteristic size cubed.

13: A method according to claim 12, further comprising, prior to producing the image,
placing the sample on a conductive pad before placing it in the scanning electron microscope, wherein the sample is a dry sample or a wet sample.

14: A method according to claim 12, wherein the image is a greyscale image and the processing includes, before the measuring, detecting particles in the image by thresholding their grey scale intensity.

15: A method according to claim 14, further comprising processing the image to reject among the detected particles conjoined particles and to conserve only separated particles, which are the usable particles.

16: A method according to claim 12, wherein the scanning electron microscope is coupled to an image analysis software.

17: A method according to claim 12, wherein the determining the geometric model takes into account a shape of the particle given by the image.

18: A method according to claim 12, wherein the processing further comprises:
calculating an equivalent diameter of the usable particles of the sample;
defining plural granulometric classes of the particles according to the equivalent diameter of the particles;
calculating a center of each granulometric class or characteristic equivalent diameter;
counting a number of particles in each granulometric class;
calculating a percentage by number of particles in each granulometric class;
converting the percentage by number of particles in each granulometric class into a percentage by volume of particles in each granulometric class;
carrying out a modelling of the size distribution of the characteristic equivalent diameters by volume;
calculating an average of the characteristic equivalent diameter of the particles;
calculating a standard deviation of the characteristic equivalent diameter of the particles.

19: A method according to claim 18, wherein the equivalent diameter is an equivalent circle diameter.

20: A method according to claim 18, wherein the modelling of the size distribution by volume of the characteristic equivalent diameters comprises calculating a cumulative increasing function from the percentage by volume of the particles in each granulometric class, calculating an expected value by application of a distribution law, modelling the distribution law with minimization of residuals of all the values of the expected value by the least squares method.

21: A method according to claim 20, wherein the distribution law is a normal or log-normal distribution law.

22: A method according to claim 18, wherein the modelling is carried out using a statistical processing software.
